(19) United States
(12) Patent Application Publication
(10) Pub. No.: US 2011/0005565 A1
(43) Pub. Date: Jan. 13, 2011

(54) Solar sphere

(75) Inventor: Eduardo Flores, Mission, TX (US)

Correspondence Address: Eduardo Flores, 3303 San Nicolas St., Mission, TX, 78573, US

(73) Assignee: Eduardo Flores, Mission, TX (US)

(21) Appl. No.: 12/459,871

(22) Filed: Jul. 10, 2009

(51) Int. Cl. H01L 31/042

(52) U.S. Cl. 136/244

(57) ABSTRACT

The Solar Sphere with the use of its tracking system can generate the same power as a solar array thirty two times its size.

### CROSS-REFERENCE TO RELATED APPLICATIONS

“Not Applicable”

### STATEMENT REGARDING FEDERALLY SPONSORED RESEARCH OR DEVELOPMENT

“Not Applicable”

### REFERENCE TO SEQUENCE LISTING, A TABLE, OR A COMPUTER PROGRAM LISTING COMPACT DISC APPENDIX

“Not Applicable”

### BACKGROUND OF THE INVENTION

The field of endeavor is the converting of radiant solar energy to electrical energy through the use of an array of solar cells configured in a solar panel. The significant problem with solar panels is that the panels occupy a large amount of area. The rough estimate is that 1200 square feet of thin layer solar cells will produce @ 35 volts at 2 to 5 Kilo watts. This invention attempts to reduce the occupied area of the solar panel array to a compacted solar panel system that has a variable output without requiring more area. One note is the use of only third generation solar cells can only be use on this invention as all others would be ineffective as far as efficiency needs.

### BRIEF SUMMARY OF THE INVENTION

The Solar Sphere is an attempt to accomplish the overcoming large surface areas needed through restructuring of the solar panel assembly through the use of a mirror. The solar sphere uses a reflective mirror to allow the array to run parallel to the solar rays. The end result is a more efficient use of area, the increase of mobility and practicality. The drawings will visually demonstrate the viability of this invention and simplicity of construction.

### BRIEF DESCRIPTION OF THE SEVERAL VIEWS OF THE DRAWING

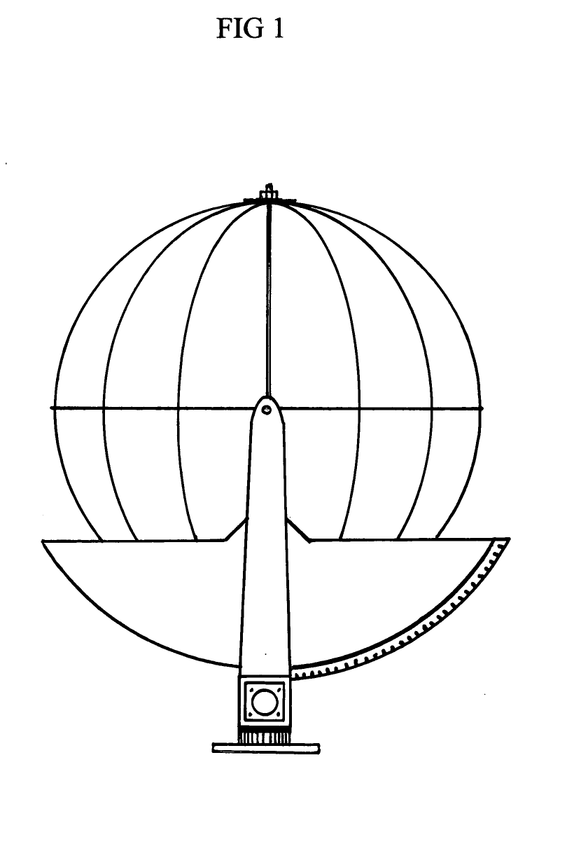

Page 1/14 FIG. 1 The Solar Sphere complete assembly side view.

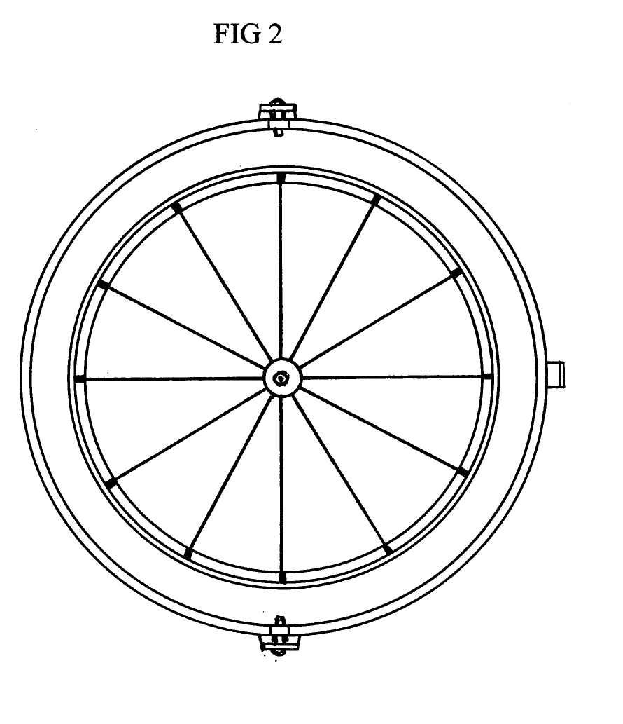

Page 2/14 FIG. 2 the Solar Sphere complete assembly top view

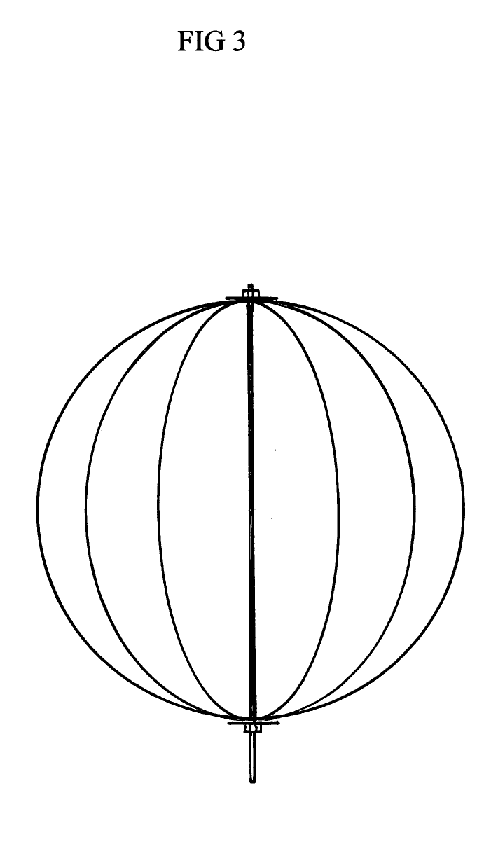

Page 3/14 FIG. 3 a side view of the solar sphere without the reflective bowl and, or tracking assembly

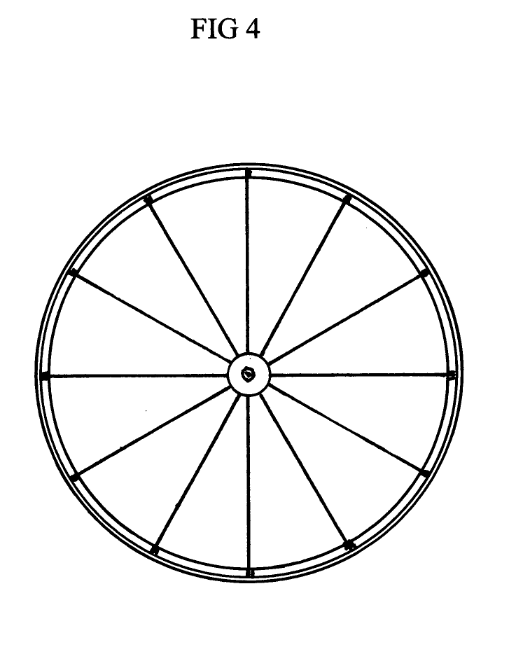

Page 4/14 FIG. 4 a top view of the solar sphere without the reflective bowl and, or tracking assembly

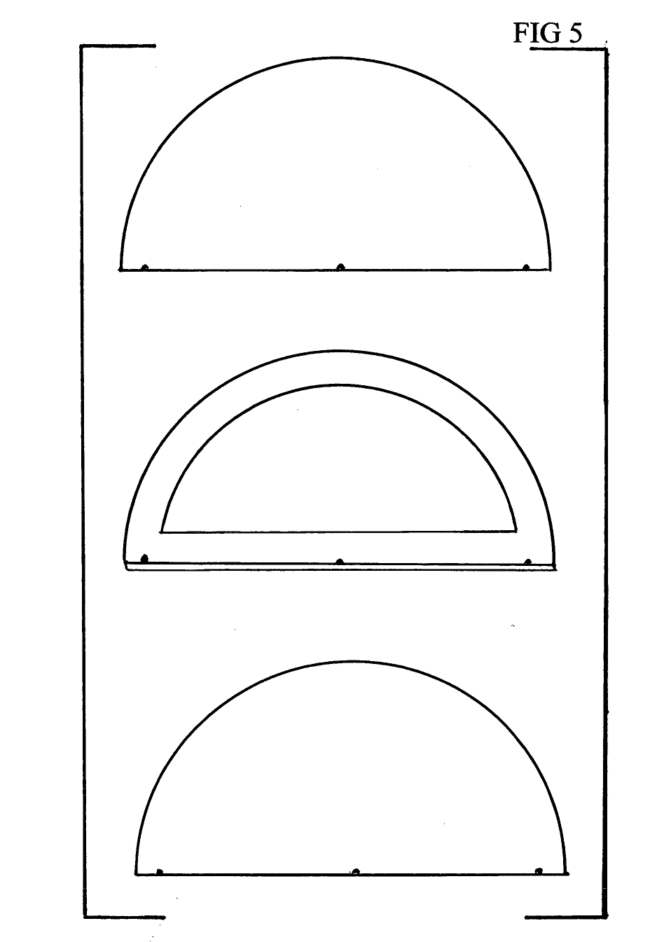

Page 5/14 FIG. 5 this is an Exploded view from the side of one of the twelve solar panels. There are two solar cell arrays, the top and bottom images of the exploded view, which are shape in half circles. These would be glued or fasten to the solar frame, the image in the middle of the exploded view. The Solar Frame would then attach to a central rod by tie wraps or other fastening devices.

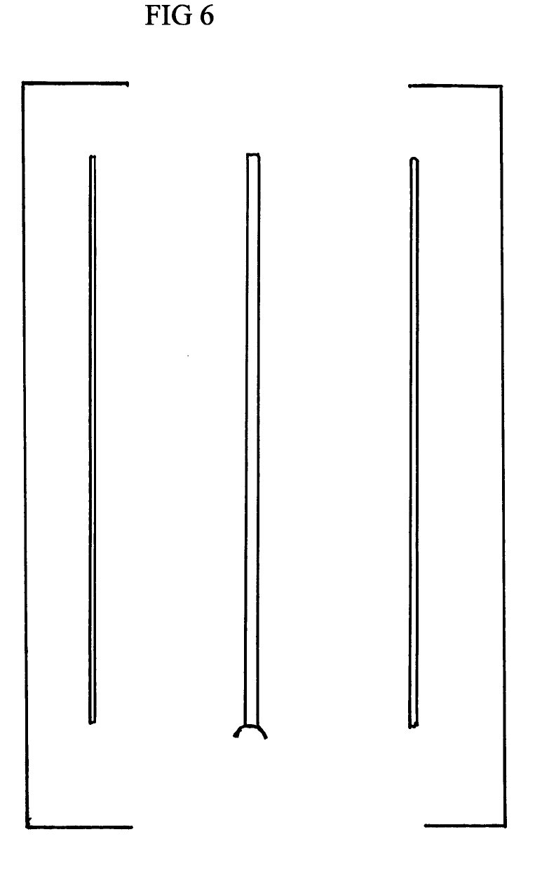

Page 6/14 FIG. 6 this is an Exploded view from end on of one of the twelve solar panels. The center image is the Solar panel frame the two outside images are the solar cell arrays. The solar cell arrays can be fastened to the frame by gluing them or by some other fastening devices. The center image (solar frame) has a curved mount point at the bottom to facilitate attachment to the support rod.

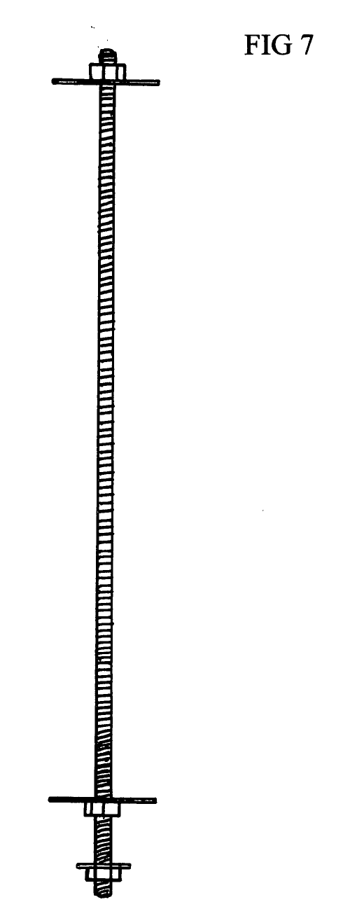

Page 7/14 FIG. 7 this is a view of the support rod which is the back bone of the sphere. Each panel has an attachment points to facilitate fastening the Solar panels to the support rod. The upper two nuts and washers secure the panels vertically and add some rigidity to the component.

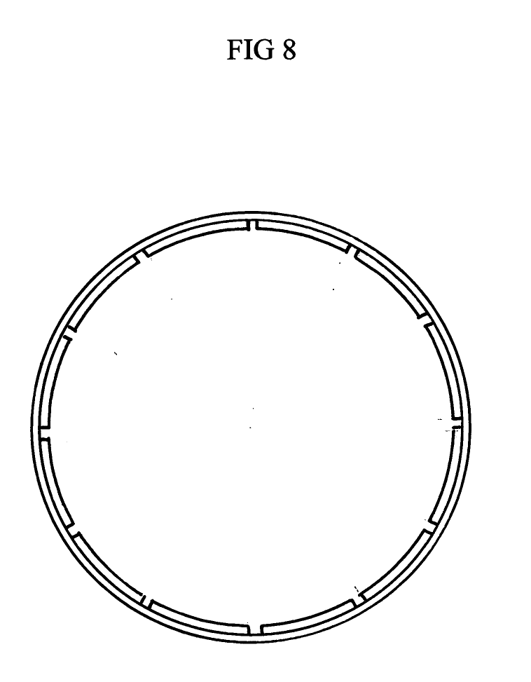

Page 8/14 FIG. 8 this is a view of the spacing ring. This ring spaces the Solar panels evenly to insure that all of the panels receive the same amount of Solar radiation. It will be slip on and maybe glued or fasten to the top of the panels.

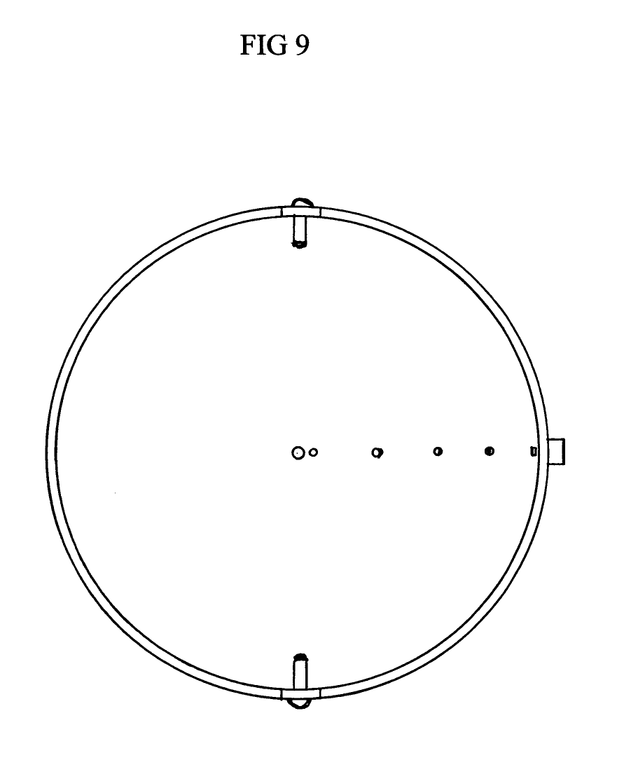

Page 9/14 FIG. 9 this is a top view of the reflective bowl. The bowl can be made of a rigid material such as metals, fiberglass, or some high heat polymer. The inner liner would be either a front surface mirror or another highly reflective substance. The attachment hole in the center would be where the solar sphere support rod would go threw to bolt it securely to the reflective bowl. The bowl also shows the bolt heads which attach the rack gear used to track the solar radiation.

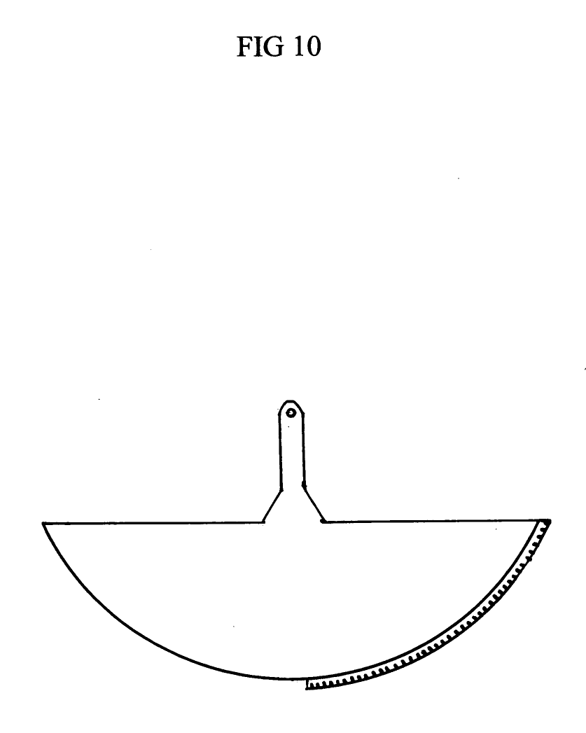

Page 10/14 FIG. 10 this is a side view of the reflective bowl showing the rack gear which will is key to tracking the maximum amount of solar radiation on a given day.

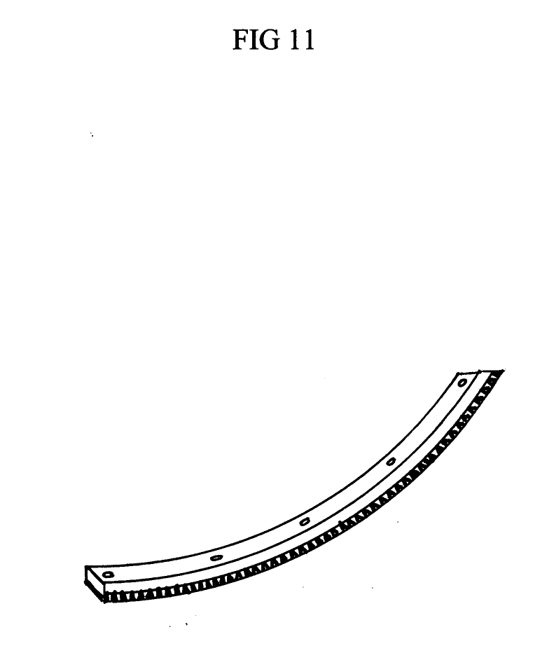

Page 11/14 FIG. 11 this is a view of the rack gear. This view is general and does not have an exact tooth ratio it merely shows that the gear rack is a separate component attach at multiple points refer to FIG. 9

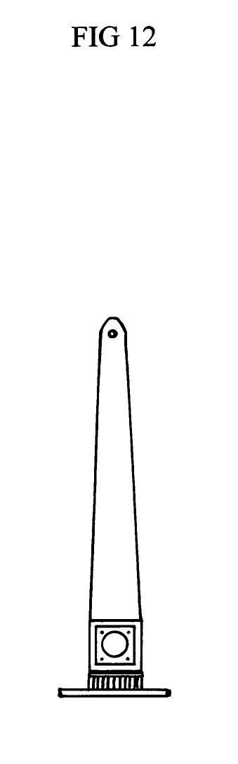

Page 12/14 FIG. 12 this is a side view of the tracking frame which is used to support the sphere and orientated toward the maximum solar radiation.

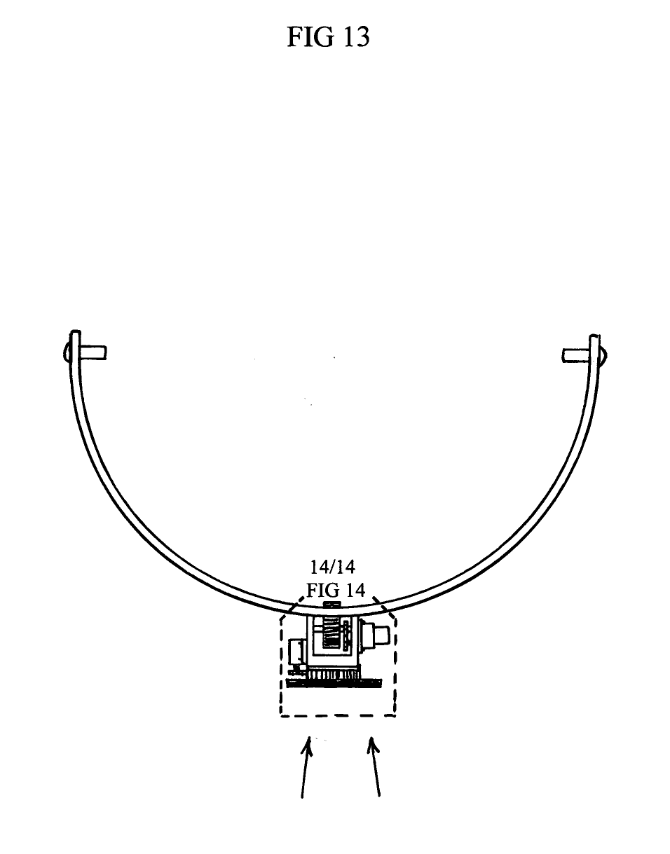

Page 13/14 FIG. 13 this is a generalized end on view of the tracking frame. It basically shows the support frame to give a perspective as it relates to the assembly of the Solar sphere.

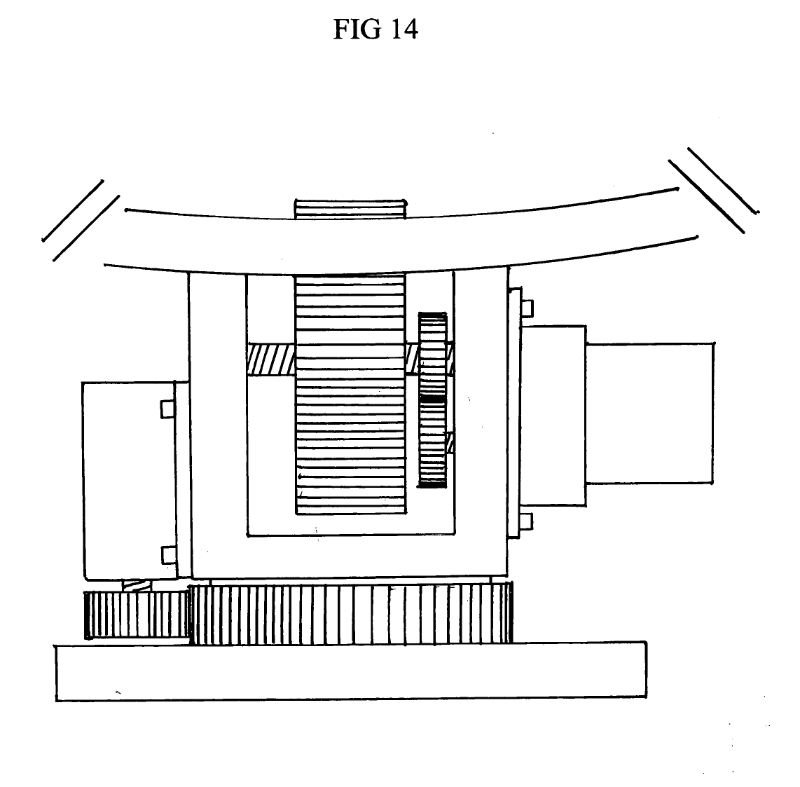

Page 14/14 FIG. 14 this is a detailed view of the tracking frames motorized gear system consisting of a tilt motor and gear system as well a rotational motor and gear system. The base plate is bolted by one central bolt to the support frame using a lubricated slip ring between the two to allow rotational movement. This motorized system changes the orientation of the sphere's assembly to gain the maximum solar input.

### DETAIL DESCRIPTION OF THE INVENTION

The Solar Sphere assembly Drawing Page 1 FIG. 1, Page 2 FIG. 2, has three parts which are an intergraded to make the solar sphere functional. The sphere, the reflective bowl and the solar tracking frame. The sphere is made up of twelve dual sided solar panels. Each solar panel is made up of a frame which supports two opposing solar cell array as shown on Drawing Page 5 FIG. 5, Page 6 FIG. 6. Each complete Solar panel is attached with tie wraps or binding straps to the threaded support rod Drawing Page 7 FIG. 7. The panels would be unevenly spaced and would bunch up on one side of the sphere thus reducing the effectives of the sphere. The spacing ring Drawing Page 8 FIG. 8 keeps the panels evenly spaced to allow the maximum amount of solar radiance to be reflected off of the reflective bowl and back to the panels. The reflective bowl Drawing Page 9 FIG. 9 Page 10 FIG. 10 is used to redirect the solar rays to the upright solar panels thus allowing the solar panels to be placed parallel to the solar rays. The reflective bowl would essentially light up the cells as a light bulb would do to a darken room. The reflective bowl is simple in construction it is one third of a full sphere @ 8 inches greater in diameter than that of the solar sphere. The inside lining is a front sided mirror or any other highly reflective material.

The reflective bowl also has a geared rack Drawing Page 11 FIG. 11 which in conjunction with the tracking frame follows the sun through out the day. The tracking frame Drawing Page 12-14 FIG. 12-14 is a concept of using two motors to tilt and rotate the solar sphere to maximize the input of solar radiance. This is done in order to achieve the 80 to 85% power levels of a standard layout of a solar array of similar area.

The Solar Sphere shown is a twelve panel, however it can be increased to 48 panels and or reduce to four without any need to increase or decrease the size of the system. The spacing Ring would be the only change as more slots would have to be created to allow for the greater number of panels. Tests have proven that on this particular Solar Sphere of 33 inches in diameter. A number of panels greater than 48 panels lead to too much shading thus negating much of the gain achieved.

An experiment was preformed to prove that solar cells could be placed parallel to the solar rays and still produce an effective output. The experiment used a standard rigid third generation solar cell 2×4 cm the output was measured at noon of a clear day in mid June. The solar cell was place perpendicular to the solar rays and measured 51 millivolts and 182 milliamps. The solar cell was then placed parallel to the solar rays and measured 30 millivolts 20 milliamps. The next step was placing a curved mirror perpendicular to the solar rays illuminating the solar cell which is still parallel to the solar rays. I measured 49 millivolts and 141 milliamps which is 75% of maximum output. The solar sphere design has a specific type of mirror made to maximize efficiency so the percentage of max output of the solar panels used should be 80 to 85% of a standard array of solar panel.

1. The Solar Sphere was invented to allow a more practical use of solar panels in various industries especially mobile industries as a supplemental power source. The industries of transportation and space exploration would benefit greatly as well as homes and small businesses. The compact feature makes the Solar cell more acceptable amongst the general populace as a supplemental power source since large surface areas are not needed. The solar sphere allows changes to power output without having to occupy a greater surface area. The addition of Solar panels is easily added with a minor change in the spacing ring.
